(19) United States
(12) Patent Application Publication
(10) Pub. No.: US 2024/0063246 A1
(43) Pub. Date: Feb. 22, 2024

(54) IMAGE SENSOR USING METHOD OF DRIVING HYBRID SHUTTER AND IMAGE PROCESSING APPARATUS INCLUDING THE SAME

(71) Applicant: SAMSUNG ELECTRONICS CO., LTD., SUWON-SI (KR)

(72) Inventor: YOUNGGU JIN, SUWON-SI (KR)

(21) Appl. No.: 18/189,349

(22) Filed: Mar. 24, 2023

(30) Foreign Application Priority Data
Aug. 22, 2022 (KR) 10-2022-0105059

(51) Int. Cl. H01L 27/146; H04N 25/59; H04N 25/531

(52) U.S. Cl. CPC H01L 27/14643; H01L 27/14612; H04N 25/59; H04N 25/531

(57) ABSTRACT

An image sensor includes: n photo diodes which respectively generate electric charges in response to incident light and are adjacent to each other; a first pixel signal output circuit shared by the n photo diodes, converts an amount of the electric charges of each the n photo diodes in order into a first pixel signal in response to a first mode signal and outputs the first pixel signal in order; and a second pixel signal output circuit which comprises a storage region shared by the n photo diodes, converts amounts of the electric charges of the n photo diodes stored together in the storage region or a voltage corresponding to the amounts of the electric charges of the n photo diode into a second pixel signal in response to a second mode signal and outputs the second pixel signal.

### CROSS-REFERENCE TO RELATED PATENT APPLICATION

This U.S. non-provisional patent application claims priority under 35 U.S.C. § 119 to Korean Patent Application No. 10-2022-0105059, filed on Aug. 22, 2022, in the Korean Intellectual Property Office, the disclosure of which is incorporated by reference in its entirety herein.

### 1. TECHNICAL FIELD

The present invention relates to an image sensor and an image processing apparatus including the same, and more particularly, to an image sensor using a method of driving a hybrid shutter and an image processing apparatus including the same.

### 2. DISCUSSION OF RELATED ART

An image sensor is a device that converts an optical image into an electric signal. There is an increasing demand for high performance image sensors in various areas such as digital cameras, camcorders, personal communication system (PCS), game devices, security cameras, medical micro cameras, and robots.

For example, high-resolution photographing may be required for an image sensor in a photo-taking mode. Also, functions that are optimized in a video-taking mode may be required for an image sensor to capture videos with distortion. However, present high performance image sensors suitable for these modes use a large amount of power and are large in size. Thus, there is a need for a smaller image sensor that uses less power.

### SUMMARY OF THE INVENTION

At least one embodiment of the present invention provides an image sensor using a method of driving a hybrid shutter which may satisfy demands for miniaturization or low power and provide optimized functions in an operation mode and an image processing apparatus including the same.

According to an aspect of the present invention, there is provided an image sensor including: n (n is an integer number above 2) photo diodes which respectively generate electric charges in response to incident light and are adjacent to each other; a first pixel signal output circuit which is shared by the n photo diodes and converts an amount of the electric charges of each the n photo diodes in order into a first pixel signal in response to a first mode signal, and outputs the first pixel signal in order; and a second pixel signal output circuit which includes a storage region shared by the n photo diodes, converts amounts of the electric charges of the n photo diodes stored together in the storage region or a voltage corresponding to the amounts of the electric charges of the n photo diodes into a second pixel signal in response to a second mode signal, and outputs the second pixel signal.

The image sensor may further include n first mode transistors each of which includes a first end connected to a corresponding photo diode from among the n photo diodes and a second other end connected to the first pixel signal output circuit and is gated in order by the first mode signal.

The first pixel signal output circuit may include: a first floating diffused region which stores the electric charges transmitted from a photo diode connected to an on-state first mode transistor from among the n first mode transistors; a first source-follower which amplifies a voltage that corresponds to an amount of the electric charges stored in the first floating diffused region; and a first selection transistor which outputs the first pixel signal that corresponds to the voltage output from the first source-follower, to a column line, in response to a column selection signal.

The first mode signal and the second mode signal may be activated at each of different times and the first pixel signal output circuit may be included in the second pixel signal output circuit.

The image sensor may further include n second mode transistors each of which includes a first end connected to a corresponding photo diode from among the n photo diodes and a second other end connected to the second pixel signal output circuit and is gated at the same time by the second mode signal.

The second pixel signal output circuit may include: a transmission transistor which comprises a first end connected to the storage region and is gated by a transmission signal; a second floating diffused region which comprises a first end connected to a second other end of the transmission transistor and stores the electric charges transmitted from the storage region; a second source-follower which amplifies a voltage that corresponds to amounts of the electric charges stored in the second floating diffused region; and a second selection transistor which outputs the second pixel signal, that corresponds to the voltage output from the second source-follower, to the column line, in response to the column selection signal.

The image sensor may further include n first mode transistors each of which includes a first end connected to a corresponding photo diode from among the n photo diodes and a second other end connected to the second floating diffused region and is gated in order by the first mode signal, wherein when n first mode transistors are turned on in order, the second floating diffused region, the second source-follower, and the second selection transistor are operated as the first pixel signal output circuit, the second floating diffused region stores in order the electric charges transmitted from a photo diode connected to a on-state first mode transistor from among the n first mode transistors, and the second selection transistor outputs the first pixel signal, that corresponds to the voltage output from the second source-follower, to the column line in order, in response to the column selection signal.

The second pixel signal output circuit may include: a second floating diffused region which stores the electric charges transmitted from n photo diodes; a (2-1)-th source-follower which transmits a voltage, that corresponds to amounts of the electric charges stored in the second floating diffused region, to a first node; a precharge transistor which comprises a first end connected to the (2-1)-th source-follower at the first node and precharges the first node, in response to a precharge signal; a sampling transistor which comprises a first end connected to the first node and a second other end connected to the storage region at a second node and is gated by a sampling signal at the first node; a (2-2)-th source-follower which comprises a gate connected to the second node and amplifies a voltage that corresponds to the storage region; and a second selection transistor which outputs the second pixel signal, that corresponds to the voltage output from the (2-2)-th source-follower, to the column line, in response to the column selection signal.

At least one of the first pixel signal output circuit and the second pixel signal output circuit may include: a floating diffused region; a dynamic range capacitor which is used to expand capacity of the floating diffused region; and a dual conversion gain transistor which connects the dynamic range capacitor to the floating diffused region in a high illuminance mode and separates the dynamic range capacitor and the floating diffused region in a low illuminance mode.

The n photo diodes may be adjacent to each other in a column direction and at least one of the first pixel signal output circuit and the second pixel signal output circuit may be shared by the n photo diodes and other n photo diodes adjacent to the corresponding photo diodes from among n photo diodes in a row direction.

The first pixel signal output circuit may convert amounts of the electric charges of some photo diodes from among n photo diodes into the first pixel signal and output the first pixel signal in order or at the same time, in response to the first mode signal, and the second pixel signal output circuit may output the second pixel signal that corresponds to amounts of the electric charges of the remaining photo diodes from among n photo diodes, in response to the second mode signal.

The first pixel signal output circuit may convert amounts of the electric charges of some photo diodes from among the n photo diodes into the first pixel signal and outputs the first pixel signal in order or at the same time, in response to the first mode signal.

The second pixel signal output circuit may output the second pixel signal that corresponds to amounts of the electric charges of some photo diodes from among the n photo diodes, in response to the second mode signal.

The first pixel signal output circuit may be operated by using a rolling shutter driving method, in response to the first mode signal, and the second pixel signal output circuit may be operated by using a global shutter driving method, in response to the second mode signal.

According to another aspect of the present invention, there is provided an image sensor including: n (n is a whole number equal 2 or higher) photo diodes which respectively generate electric charges in response to incident light and are adjacent to each other; n first mode transistors which overlap a first region of a corresponding photo diode from among the n photo diodes while being spaced apart from one another in a first direction; a storage region shared by the n photo diodes; and n second mode transistors which overlap a second region adjacent to the storage region of a corresponding photo diode from among the n photo diodes while being spaced apart from one another in the first direction.

The storage region may be formed on a position where the sum of distances spaced apart from each of the n photo diodes is the smallest.

The first region and the second region may be spaced apart from each other by a maximum distance in a corresponding photo diode.

The image sensor may further include first floating diffused regions each shared by an adjacent first mode transistor from among n first mode transistors.

The n first mode transistors may be turned on in order and the n second mode transistors may be turned on at the same time.

According to another aspect of the present invention, there is provided an image processing apparatus including: the image sensor described above; and an image processor which receives the digital pixel signal corresponding to the first pixel signal or the second pixel signal from the image sensor and generates image data.

### BRIEF DESCRIPTION OF THE DRAWINGS

The above and other features of the present invention will become more apparent by describing in detail exemplary embodiments thereof with reference to the attached drawings in which:

FIG. 1 is a block diagram illustrating an image sensor according to an embodiment of the present invention;

FIGS. 2 and 3 are block diagrams respectively illustrating a unit pixel according to an embodiment of the present invention;

FIG. 4 is a circuit diagram illustrating a unit pixel according to an embodiment of the present invention;

FIGS. 5 and 6 are timing diagrams respectively illustrating the operation of the unit pixel of FIG. 4;

FIG. 7 is a circuit diagram illustrating a unit pixel according to an embodiment of the present invention;

FIG. 8 is a block diagram illustrating a unit pixel according to an embodiment of the present invention;

FIGS. 9 and 10 are circuit diagrams respectively illustrating the unit pixel of FIG. 8;

FIGS. 11 and 12 respectively illustrate a unit pixel including a dual conversation gain function according to an embodiment of the present invention;

FIGS. 13 and 14 are respectively a block diagram and a circuit diagram illustrating a unit pixel where a first and/or a second pixel signal output unit is shared by a photo diode adjacent in a row direction according to an embodiment of the present invention;

FIG. 15 illustrates a layout of a unit pixel according to an embodiment of the present invention;

FIG. 16 is a circuit diagram that corresponds to the unit pixel of FIG. 15;

FIG. 17 illustrates a layout of a unit pixel where a first floating diffused region is shared according to an embodiment of the present invention;

FIG. 18 is a circuit diagram that corresponds to the unit pixel of FIG. 17;

FIG. 19 illustrates a unit pixel including an auto focusing function according to an embodiment of the present invention; and

FIG. 20 illustrates an image processing apparatus according to an embodiment of the present invention.

### DETAILED DESCRIPTION OF THE EMBODIMENTS

Hereinafter, embodiments of the present invention are described in detail and clearly to such an extent that one of ordinary skill in the art may implements the same.

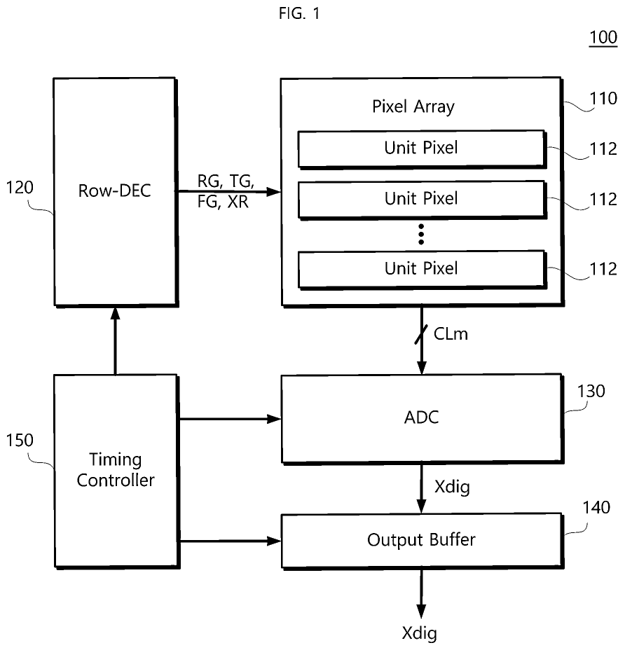

FIG. 1 is a block diagram illustrating an image sensor 100 according to an embodiment of the present invention.

Referring to FIG. 1, the image sensor 100 according to an embodiment of the present invention includes a pixel array 110, a row decoder 120 (e.g., a decoder circuit), an analog-digital converter (ADC) 130, an output buffer 140, and a timing controller 150 (e.g., a control circuit).

The pixel array 110 includes a plurality of unit pixels 112. The plurality of unit pixels 112 may be arranged, for example, in a matrix form. The pixel array 110 may receive pixel driving signals such as a row selection signal XR, a reset signal RG, a transmission signal TG, and a floating control signal FG from the row decoder 120. The pixel array 110 is operated according to control of the received pixel driving signals and the unit pixels 112 may each convert an optical signal into an electric signal. Also, electric signals generated by each of the unit pixels 112 may be provided to the ADC 130 through a plurality of column lines CLm.

According to an embodiment of the present invention, the plurality of unit pixels 112 included in the pixel array 110 may each be operated using a method of driving a hybrid shutter. The unit pixels 112 may be operated using a shutter driving method which is optimized with respect to performances and power consumption according to an operation mode of the image sensor 100. For example, when high-resolution photographing is required by using the image sensor 100, the unit pixels 112 may be operated using a rolling shutter driving method. When video taking or capturing is performed in the image sensor 100, the unit pixels 112 may be operated using a global shutter driving method.

A structure and operation of each unit pixel 112 according to an embodiment of the present invention, will be described in more detail below with reference to the accompanying drawings.

The row decoder 120 may select any one row of the pixel array 110 according to control of the timing controller 150. The row decoder 120 may generate the row selection signal XR to select any one row from among a plurality of rows. Also, the row decoder 120 may activate the reset signal RG, the transmission signal TG, and the floating control signal FG according to a fixed order with respect to the unit pixels that correspond to the selected row. Then, a reset level signal and a sensing signal generated from each unit pixel 112 of the selected row may be transmitted to the ADC 130.

The ADC 130 may convert the reset level signal and the sensing signal into digital signals and output the converted signal. For example, the ADC 130 may sample the reset level signal and the sensing signal by using correlated double sampling and then, convert the sampled signals into digital signals. In this regard, the ADC 130 may further include a correlated double sampler (CDS) at the front end thereof.

The output buffer 140 may latch and output a digital signal Xdig in a column unit provided by the ADC 130. The output buffer 140 may temporarily store the digital signal Xdig output from the ADC 130 according to control of the timing controller 150 and then, output the digital signal Xdig which is latched in order according to a column decoder.

The timing controller 150 may control the pixel array 110, the row decoder 120, the ADC 130, and the output buffer 140. The timing controller 150 may provide control signals such as a clock signal and a timing control signal for operations of the pixel array 110, the row decoder 120, the ADC 130, and the output buffer 140. The timing controller 150 may include a logic control circuit, a phase lock loop, a timing control circuit, and a communication interface circuit.

The structure of the image sensor 100 according to an embodiment of the present invention is briefly described above. According to an embodiment of the present invention, each of the unit pixels 112 included in the pixel array 110 has a structure that may be operated using functions optimized for a certain operation mode and may realize miniaturization or low power consumption. The unit pixels 112 will be described in more detail below.

Hereinafter, when the same structures are repeated in the pixel array 110, the unit pixel 112 according to an embodiment of the present invention may denote a minimum unit of the repeated structures or a minimum unit required to explain functions of the repeated structures.

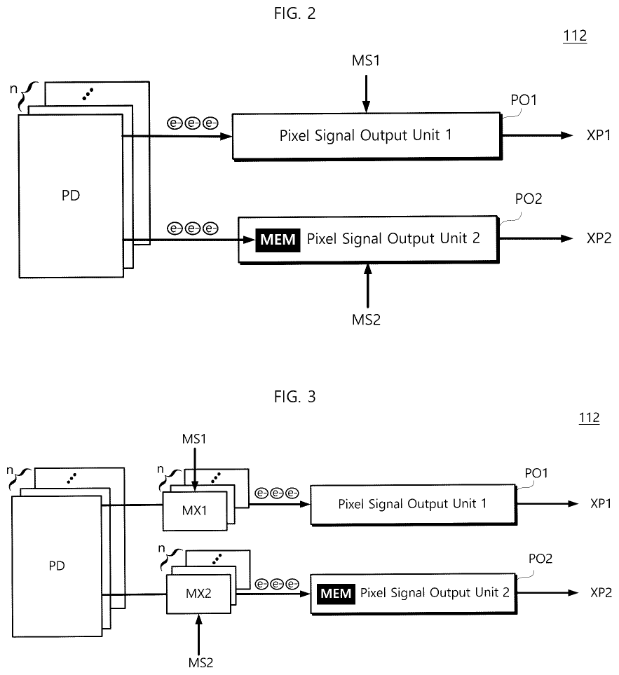

FIGS. 2 and 3 are block diagrams respectively illustrating the unit pixel 112 according to an embodiment of the present invention.

First, referring to FIGS. 1 and 2, the unit pixel 112 according to an embodiment of the present invention includes n (n is a whole number or integer equal to 2 or higher) photo diodes PDs, a first pixel signal output unit PO1 (e.g., a first pixel output circuit), and a second pixel signal output unit PO2 (e.g., a second pixel output circuit).

The photo diode PD is a light-sensing device which generates and integrates electric charges according to an amount or intensity of incident light. The photo diode PD may be realized as a photo transistor, a photo gate, a pinned photo diode (PPD), an organic photo diode (OPD), or a quantum dot (QD). An ion implantation process may be performed so that the photo diode PD is formed in an N-type region or a P-type region within a well region of a substrate. Also, the photo diode PD may be formed in such a way that a plurality of doping regions is stacked.

Two, four, or eight photo diodes PDs may be included in the unit pixel 112. The number of the photo diodes PDs included in the unit pixel 112 may vary according to performance, an area, or electric power required of the image sensor 100.

The n photo diodes PDs included in the unit pixel 112 may be adjacent to each other. For example, n photo diodes PDs included in the unit pixel 112 may be adjacent to each other in one direction (for example, a column direction or row direction) or in both directions (for example, a column and a row direction) on the pixel array 110. For example, the n photo diodes PDs may be arranged in a single row, a single column, or a matrix of rows and columns.

The first pixel signal output unit PO1 converts an amount of electric charges of each n photo diodes PDs into first pixel signals XP1 and outputs the first pixel signals XP1 in order, in response to a first mode signal MS1. The first pixel signal output unit PO1 may convert an amount of an electric charge of a first PD into a (1-1)-th first pixel signal and output the (1-1)-th first pixel signal. Then, the first pixel signal output unit PO1 may convert an amount of an electric charge of a second photo diode PD into a (1-2)-th first pixel signal and output the (1-2)-th first pixel signal.

The second pixel signal output unit PO2 includes one storage region MEM shared with n photo diodes PDs. The storage region MEM may include a diode or a capacitor. When the storage region MEM is a diode, an ion implantation process may be performed so that an N-type or a P-type region is formed in a well region (not illustrated) of a substrate. Also, the storage region MEM may include a plurality of stacked doping regions.

The electric charges transmitted from n photo diodes PDs may be stored together in the storage region MEM. The second pixel signal output unit PO2 may convert amounts of the electric charges of the n photo diodes PDs stored in the storage region MEM or the voltage of the amounts of the electric charges of the n photo diodes PDs into a second pixel signal XP2 and output the second pixel signal XP2, in response to a second mode signal MS2.

Hereinafter, for convenience of description, unless otherwise noted, it is described that the electric charges of the n photo diodes PDs are stored together in the storage region MEM. FIG. 2 also illustrates that electric charges of photo diodes PDs are directly transmitted to the storage region MEM. However, it does not denote that the voltage that corresponds to the sum of the electric charges of n photo diodes PDs may not be applied to in the storage region MEM. It should be understood that other embodiments below are in the same manner.

As described above, the first pixel signal output unit PO1 may process the electric charges of the n photo diodes PDs in order and the second pixel signal output unit PO2 may process the electric charges of the n photo diodes PDs at the same time. Accordingly, the first pixel signal output unit PO1 may output a relatively high-resolution image, whereas the second pixel signal output unit PO2 may output an image with relatively low power. For example, when the second pixel signal output unit PO2 is separately included for each of the photo diodes PDs, the area and the power may be reduced to 1/n.

In this regard, the image sensor 100 according to an embodiment of the present invention processes the electric charges of the photo diodes PDs using each different shutter in the unit pixel 112. Accordingly, images optimized for a certain operation mode may be provided and miniaturization and low power consumption may be realized.

FIG. 2 illustrates a connection between one photo diode PD from among n photo diodes PDs and the first and second pixel signal output units PO1 and PO2 only for the convenience of illustration. However, each of n photo diodes PDs may be electrically connected to the first pixel signal output unit PO1 and the second pixel signal output unit PO2, and the same shall apply hereinafter.

Next, referring to FIG. 3, the unit pixel 112 according to an embodiment of the present invention may further include first mode transistors MX1 and second mode transistors MX2 which correspond to the number of photo diodes PDs.

One ends of the first mode transistors MX1 may each be connected to a corresponding photo diode PD from among the n photo diodes PDs, the other ends thereof may each be connected to the first pixel signal output unit PO1, and the first mode transistors MX1 may be gated in order by the first mode signal MS1. For example, the first mode signal MS1 may be applied sequentially to a gate of each of the first mode transistors MX1. One ends of the second mode transistor MX2 may each be connected to a corresponding photo diode PD from among the n photo diodes PDs, the other ends thereof may each be connected to the storage region MEM, and the second mode transistors MX2 may be gated along with the second mode signal MS2. For example, the second mode signal MS2 may be applied to a gate of each of the second mode transistors MX2 at the same or substantially the same time.

FIG. 3 illustrates that each number of the first mode transistors MX1 and the second mode transistors MX2 is the same as the number of the photo diodes PD, however, the present invention is not limited thereto. For example, according to an operational condition of the image sensor 100 including unit pixel 112 according to an embodiment of the present invention, various numbers of the first mode transistor MX1 and the second mode transistor MX2 may be present with respect to n PDs, such as n/2 first mode transistor MX1.

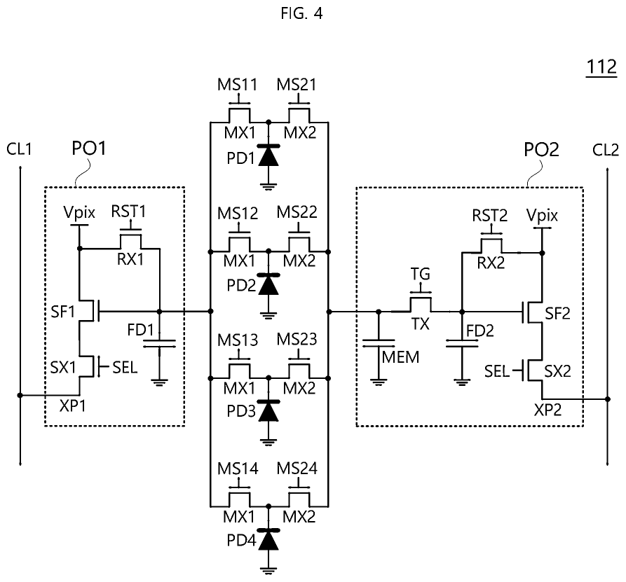

FIG. 4 is a circuit diagram illustrating the unit pixel 112 according to an embodiment of the present invention.

Referring to FIGS. 3 and 4, the unit pixel 112 according to an embodiment of the present invention includes four photo diodes PDs, the first pixel signal output unit PO1, the second pixel signal output unit PO2, four first mode transistors MX1, and four second mode transistors MX2.

Four photo diodes PDs may be adjacent to each other in a row and column direction (2×2) or a column direction (1×4). FIG. 4 illustrates the latter. One end of each photo diode PD may be connected to the first mode transistor MX1 and the second mode transistor MX2.

The first mode transistor MX1 may be gated by the first mode signal MS1 and may transmit the electric charge of the photo diode PD to the first pixel signal output unit PO1. For example, the first mode transistor MX1 is turned on by an (1-1)-th mode signal MS11 and may transmit the electric charge of a first photo diode PD1 to the first pixel signal output unit PO1. Also, the first mode transistor MX1 is turned on by a (1-2)-th mode signal MS12 and may transmit the electric charge of a second photo diode PD2 to the first pixel signal output unit PO1. As in the same manner, the first mode transistor MX1 is turned on by a (1-3)-th mode signal MS13 and may transmit the electric charge of a third photo diode PD3 to the first pixel signal output unit PO1. Also, the first mode transistor MX1 is turned on by a (1-4)-th mode signal MS14 and may transmit the electric charge of a fourth photo diode PD4 to the first pixel signal output unit PO1.

The first pixel signal output unit PO1 may include a first floating diffused (or diffusion) region FD1, a first source-follower SF1, and a first selection transistor SX1.

The first floating diffused region FD1 may store the electric charge transmitted from the photo diode PD connected to an on-state first mode transistor from among four first mode transistors MX1. FIG. 4 illustrates that the first pixel signal output unit PO1 includes one first floating diffused region FD1. However, the present invention is not limited thereto and the first pixel signal output unit PO1 may further include the first floating diffused region FD1 according to the required intensity of the first pixel signal XP1.

The first source-follower SF1 may amplify the voltage that corresponds to an amount of the electric charge stored in the first floating diffused region FD1. A gate of the first source-follower SF1 may be connected to the first floating diffused region FD1 and one end of the first source-follower SF1 may be connected to a power voltage Vpix. The first source-follower SF1 may be coupled with the first floating diffused region FD1. The first source-follower SF1 may be implemented by a transistor.

The first selection transistor SX1 may output the first pixel signal XP1, which corresponds to the voltage output from the first source-follower SF1, to a first column line CL1, in response to a column selection signal SEL. The column selection signal SEL may be applied from the row decoder 120 of FIG. 1. The first pixel signal XP1 may be converted into a digital signal through the ADC 130 of FIG. 1 and the digital signal may be output as image data in a fixed unit through the output buffer 140 of FIG. 1.

The first pixel signal output unit PO1 may further include a first reset transistor RX1. The first reset transistor RX1 may reset the first floating diffused region FD1, in response to a first reset signal RST1. When the first reset transistor RX1 is turned on, a terminal, to which the power voltage Vpix is applied, may be electrically connected to the first floating diffused region FD1. In this case, the electric charge integrated to the first floating diffused region FD1 is drained to the terminal of the power voltage Vpix and then, the first floating diffused region FD1 may be reset to the level of the power voltage Vpix.

The second mode transistor MX2 may be gated by the second mode signal MS2 and may transmit the electric charge of the photo diode PD to the second pixel signal output unit PO2. For example, the electric charge of the photo diode PD may be transmitted to the storage region MEM of the second pixel signal output unit PO2. For example, the second mode transistor MX2 is turned on by a (2-1)-th mode signal MS21 and may transmit the electric charge of the first photo diode PD1 to the second pixel signal output unit PO2. Also, the second mode transistor MX2 is turned on by a (2-2)-th mode signal MS22 and may transmit the electric charge of the second photo diode PD2 to the second pixel signal output unit PO2. As in the same manner, the second mode transistor MX2 is turned on by a (2-3)-th mode signal MS23 and may transmit the electric charge of the third photo diode PD3 to the second pixel signal output unit PO2. Also, the second mode transistor MX2 is turned on by a (2-4)-th mode signal MS24 and may transmit the electric charge of the fourth photo diode PD4 to the second pixel signal output unit PO2.

In an embodiment, the second pixel signal output unit PO2 includes the storage region MEM, a transmission transistor TX, a second floating diffused (e.g., diffusion) region FD2, a second source-follower SF2, and a second selection transistor SX2.

One end of the storage region MEM may be connected to the second mode transistor MX2. As described above, the storage region MEM may store the electric charges transmitted from the first photo diode PD1 through fourth photo diode PD4 at the same time.

The transmission transistor TX may be connected to the other end of the storage region MEM and may be gated by the transmission signal TG. When the transmission transistor TX is turned on by the transmission signal TG, the storage region MEM and the second floating diffused region FD2 may be electrically connected to each other. Accordingly, the electric charge integrated to the storage region MEM may move to the second floating diffused region FD2. The transmission signal TG may be applied from the row decoder 120 of FIG. 1.

The voltage that corresponds to amounts of the electric charge moved to and stored in the second floating diffused region FD2 may be amplified by the second source-follower SF2 and may be output as the second pixel signal XP2 through the second selection transistor SX2, which is turned on by the column selection signal SEL. The second source-follower SF2 may be implemented by a transistor. The second pixel signal XP2 may be output to a second column line CL2.

As described with reference to the first pixel signal output unit PO1 above, a plurality of the second floating diffused regions FD2 may be included and the second pixel signal XP2 may be finally output as an image data.

The second pixel signal output unit PO2 may further include a second reset transistor RX2 including one end connected to the second floating diffused region FD2 and the other end connected to a node receiving a power voltage Vpix, wherein the second reset transistor RX2 is gated, in response to a second reset signal RST2. The second reset transistor RX2 may reset the second floating diffused region FD2 by activation of the second reset signal RST2. When the second reset transistor RX2 is turned on, the terminal, to which the power voltage Vpix is applied, and the second floating diffused region FD2 may be electrically connected to each other. In this case, the electric charge integrated to the second floating diffused region FD2 is drained to the terminal of the power voltage Vpix and then, the second floating diffused region FD2 may be reset to the level of the power voltage Vpix.

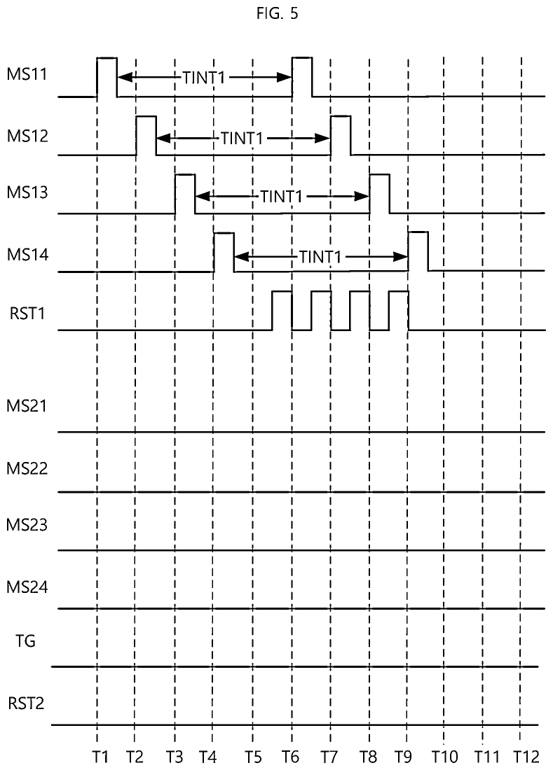

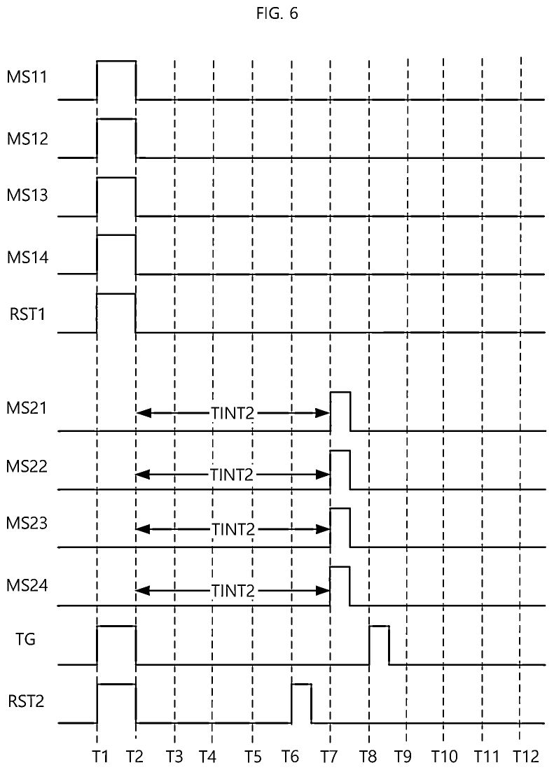

FIGS. 5 and 6 are timing diagrams respectively illustrating an operation of the unit pixel 112 of FIG. 4.

First, referring to FIGS. 4 and 5, the unit pixel 112 according to an embodiment of the present invention is operated using a shutter driving method of a first mode. Since the (1-1)-th mode signal MS11 through the (1-4)-th mode signal MS14 are activated in order between time T1 and time T4 and between time T6 and T9, the electric charges of the first photo diode PD1 through the fourth photo diode PD4 are transmitted to the first pixel signal output unit PO1. Accordingly, the first pixel signal output unit PO1 operates as described above so as to output the first pixel signals XP1 that correspond to the electric charges of the first photo diode PD1 through the fourth photo diode PD4 to the first column line CL1 in order. On the other hand, the (2-1)-th mode signal MS21 through the (2-4)-th mode signal MS24 are deactivated between time T1 and time T12.

The first photo diode PD1 through the fourth photo diode PD4 integrate the electric charges again from time T6 to time T9 when the (1-1)-th mode signal MS11 through the (1-4)-th mode signal MS14 are activated again, that is, during first integrated time TINT1. The electric charges integrated to the first photo diode PD1 through the fourth photo diode PD4 during the first integrated time TINT1 are transmitted in order to the first floating diffused region FD1 from time T6 to time T9. Accordingly, the first reset signal RST1 is activated to reset the first floating diffused region FD1, before the electric charge is transmitted to the first pixel signal output unit PO1 from the photo diode PD electrically connected to the first pixel signal output unit PO1 from among the first photo diode PD1 through the fourth photo diode PD4 from time T6 to time T9.

Since the starting point and the end point of the first integrated time TINT1 are different from each other with respect to the photo diodes PDs which are in different rows in the unit pixel 112, the shutter driving method of the first mode may be referred to a rolling shutter driving method.

Next, referring to FIGS. 4 and 6, the unit pixel 112 according to an embodiment of the present invention is operated using a shutter driving method of a second mode. The (2-1)-th mode signal MS21 through the (2-4)-th mode signal MS24 are simultaneously activated at time T7. The first photo diode PD1 through the fourth photo diode PD4 integrate the electric charges during second integrated time TINT2 until T7 when the (2-1)-th mode signal MS21 through the (2-4)-th mode signal MS24 are activated. FIG. 6 illustrates that the second integrated time TINT2 is from time T2 to time T7.

The electric charges integrated to the first photo diode PD1 through the fourth photo diode PD4 during the second integrated time TINT2 are simultaneously transmitted and stored in the storage region MEM of the second pixel signal output unit PO2 at time T7.

Since the transmission signal TG is activated at time T8, the electric charges stored in the storage region MEM are transmitted to the second floating diffused region FD2. Accordingly, the second reset signal RST2 is activated to reset the second floating diffused region FD2 before time T8.

The electric charges of the first photo diode PD1 through the fourth photo diode PD4 stored in the second floating diffused region FD2 are generated as one corresponding second pixel signal XP2 according to the operation of the second pixel signal output unit PO2 described above and the second pixel signal XP2 is output to the second column line CL2.

Here, in the unit pixel 112 according to an embodiment of the present invention, the (1-1)-th mode signal MS11 through the (1-4)-th mode signal MS14, the first reset signal RST1, the second reset signal RST2, and the transmission signal TG may be all turned on between time T1 and time T2 and the electric charges integrated to the first photo diode PD1 through the fourth photo diode PD4 may be all drained. Accordingly, the second pixel signal XP2 may be accurately generated after the (2-1)-th mode signal MS21 through the (2-4)-th mode signal MS24 are activated at time T7. Unlike FIG. 6, some of the signals may not be turned on at time T1, if needed.

Since the starting point and the end point of the second integrated time TINT2 are the same with each other with respect to the photo diodes PDs which are in different rows in the unit pixel 112, the shutter driving method of the second mode may be referred to a global shutter driving method.

The rolling shutter driving method may be suitable for high-resolution photographing. According to the rolling shutter driving method in which the electric charges of the photo diodes PDs, which are in different rows, are processed in order, distortion such as wobble or skewing may be generated due to a difference in the integrating times for each photo diode PD while capturing an object moving at high speed. On the other hand, relatively small area and low power are required due to the operations performed in order so that high-resolution photographing may be relatively available under the same condition in terms of the area and power.

According to the global shutter driving method in which the electric charges of the photo diodes PDs, which are in different rows, are processed at the same time, distortion of images generated due to a difference in the integrating times for each photo diode PD may be removed and thus, the global shutter driving method may be suitable for capturing of moving objects. On the other hand, the global shutter driving method may need a relatively big pixel area due to the storage region MEM. In the global shutter driving method, a plurality of photo diodes PDs is processed at the same time and thus, relatively great power may be required. For example, a unit pixel in the global shutter driving method may have an area which is four times greater than a unit pixel in the rolling shutter driving method.

Since the unit pixel 112 according to an embodiment of the present invention includes the second pixel signal output unit PO2, the global shutter driving method, in which a relatively big pixel area is consumed, is performed in unit of n photo diode PDs so that the distortion generated while capturing a high-speed moving object may be prevented, and the area and power may be reduced by 1/n. Also, the unit pixel 112 according to an embodiment of the present invention includes the first pixel signal output unit PO1 to enable high-resolution photographing for stopped or low-speed moving objects at low power.

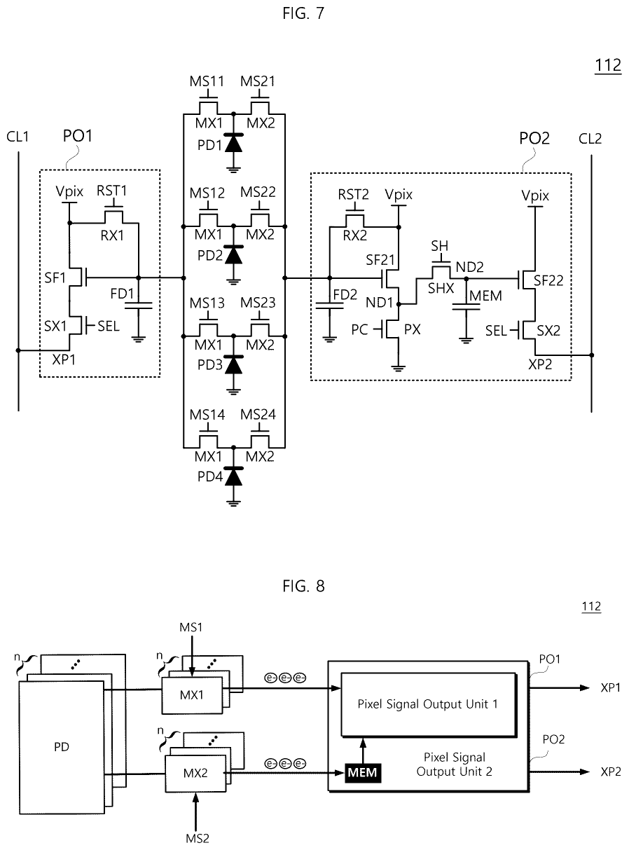

FIG. 7 is a circuit diagram illustrating the unit pixel 112 according to an embodiment of the present invention.

Referring to FIG. 7, the unit pixel 112 according to an embodiment of the present invention may include four photo diodes PDs, the first pixel signal output unit PO1, the second pixel signal output unit PO2, four first mode transistors MX1, and four second mode transistors MX2, as illustrated in FIG. 4. The second pixel signal output unit PO2 of FIG. 4 generates the second pixel signal XP2 using the global shutter applying a charge domain method, whereas the second pixel signal output unit PO2 of FIG. 7 generates the second pixel signal XP2 using the global shutter applying a voltage domain method.

In this regard, the second pixel signal output unit PO2 may include the second floating diffused region FD2, a (2-1)-th source-follower SF21, a precharge transistor PX, a sampling transistor SHX, the storage region MEM, a (2-2)-th source-follower SF22, and the second selection transistor SX2.

The second floating diffused region FD2 may store the electrical charges transmitted from the first photo diode PD1 through the fourth photo diode PD4 together. The second floating diffused region FD2 may be electrically connected to the second mode transistor MX2. The (2-1)-th source-follower SF21 may be coupled with the second floating diffused region FD2 and may transmit a voltage, which corresponds to the amounts of the electric charge of the second floating diffused region FD2, to a first node ND1. One end of the precharge transistor PX is connected to the (2-1)-th source-follower SF21 at the first node ND1 and the precharge transistor PX may precharge the first node ND1, in response to a precharge signal PC. For example, the precharge signal PC may be applied to a gate of the precharge transistor PX. Here, the first node ND1 may be reset. The sampling transistor SHX may include one end connected to the first node ND1 and other end connected to the storage region MEM at a second node ND2, and may be gated by a sampling signal SH. Accordingly, the voltage of the first node ND1 may be transmitted to the second node ND2 only when the sampling transistor SHX is turned on. The storage region MEM connected to the second node ND2 may store the voltage which corresponds to the sum of the electric charges of the first photo diode PD1 through the fourth photo diode PD4 transmitted to the second node ND2. The (2-2)-th source-follower SF22 may include a gate connected to the second node ND2 and may be coupled with storage region MEM. The second selection transistor SX2 may output the second pixel signal XP2, which corresponds to the voltage output from the (2-2)-th source-follower SF22, to the second column line CL2, in response to the column selection signal SEL.

The global shutter structure applying the charge domain method, in which the electric charges of the first photo diode PD1 through the fourth photo diode PD4 are stored in the storage region MEM and are processed as the second pixel signal XP2 as illustrated in FIG. 4, may have a relatively reduced complexity of a pixel structure, compared to the global shutter structure applying the voltage domain method illustrated in FIG. 7. The global shutter structure applying the voltage domain method, in which the voltages corresponding to the amounts of the electric charges of the first photo diode PD1 through the fourth photo diode PD4 are applied to the storage region MEM and are processed as the second pixel signal XP2 as illustrated in FIG. 7, may have relatively reduced leakage of light, compared to the global shutter structure applying the charge domain method illustrated in FIG. 4.

The second pixel signal output unit PO2 according to an embodiment of the present invention may perform the global shutter function using the charge domain method and the voltage domain method according to the required performance and condition. FIGS. 4 and 7 respectively illustrate the global shutter structure applying the charge domain method and the voltage domain method. However, the present invention is not limited thereto and various other structures may be applied to the charge domain method and the voltage domain method. Also, the first pixel signal output unit PO1 according to an embodiment of the present invention may have various structures for performing a rolling shutter function.

FIG. 8 is a block diagram illustrating the unit pixel 112 according to an embodiment of the present invention.

Referring to FIG. 8, the unit pixel 112 according to an embodiment of the present invention includes n photo diodes PDs, the first pixel signal output unit PO1, the second pixel signal output unit PO2, the first mode transistors MX1, and the second mode transistors MX2 as illustrated in FIG. 3. Unlike FIG. 3 where the first pixel signal output unit PO1 and the second pixel signal output unit PO2 are separately included, the first pixel signal output unit PO1 of FIG. 8 is included in the second pixel signal output unit PO2 in the unit pixel 112.

Here, the first mode signal MS1 and the second mode signal MS2 are activated at different times. Accordingly, the second pixel signal output unit PO2 may function as the first pixel signal output unit PO1 of FIG. 3, in which the electric charges integrated to n photo diodes PDs are processed as the first pixel signal XP1 in order at one time point, whereas the second pixel signal output unit PO2 may function as the second pixel signal output unit PO2 of FIG. 3, in which the electric charges integrated to n photo diodes PDs are processed at the same time as the second pixel signal XP2 at other time point. For example, the pixel signal output unit PO2 may operate in turn on outputs of each of the n photo diodes PDs during a first time when the first mode signal MS1 is activated and the second mode signal MS2 is inactivated, and then operate on output of the storage region MEM during a second other time when the first mode signal MS1 is inactivated and the second mode signal MS2 is activated.

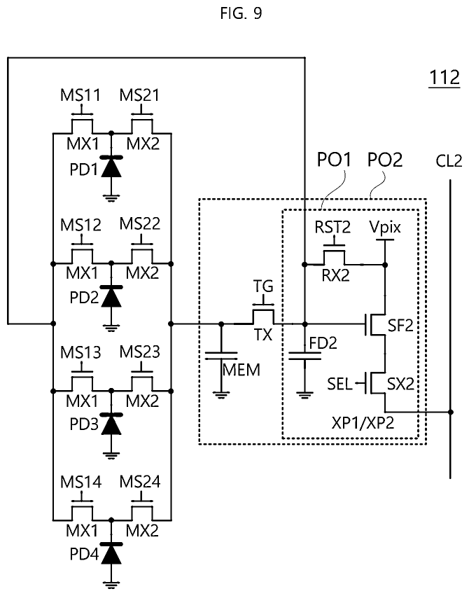

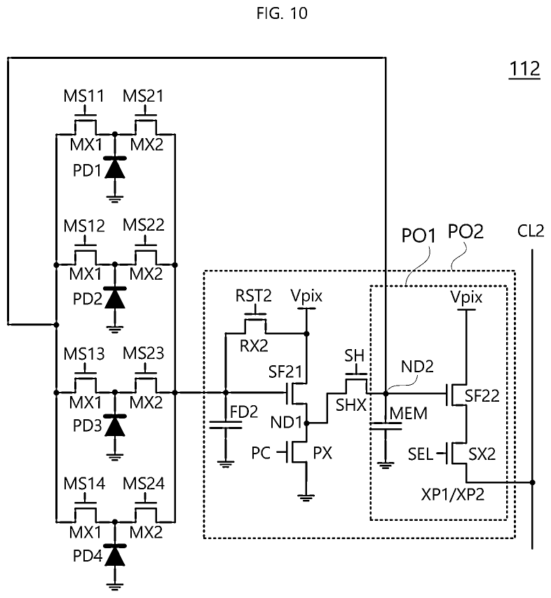

FIGS. 9 and 10 are circuit diagrams respectively illustrating the unit pixel 112 of FIG. 8.

First, referring to FIGS. 8 and 9, the second pixel signal output unit PO2 may be operated using the global shutter applying the charge domain method, similarly to FIG. 4. On the other hand, unlike FIG. 4, where the first pixel signal output unit PO1 and the second pixel signal output unit PO2 are separately included, the first pixel signal output unit PO1 may be included in the second pixel signal output unit PO2.

For example, the first pixel signal output unit PO1 may convert an amount of the electric charges integrated to the first photo diode PD1 through the fourth photo diode PD4 into the first pixel signals XP1 in order through the second floating diffused region FD2, the second source-follower SF2, and the second selection transistor SX2, when the (1-1)-th mode signal MS11 through the (1-4)-th mode signal MS14 are activated. The first pixel signals XP1 may be output to the second column line CL2 in order.

Here, the second floating diffused region FD2 may be electrically connected to the first photo diode PD1 through the fourth photo diode PD4 through the first mode transistor MX1. The operations of the second source-follower SF2 and the second selection transistor SX2 with respect to the electric charges of the first photo diode PD1 through the fourth photo diode PD4 stored in order in the second floating diffused region FD2 may be the same as those of the first source-follower SF1 and the first selection transistor SX1 described above with reference to FIGS. 4 and 5.

Next, referring to FIGS. 8 and 10, the second pixel signal output unit PO2 may be operated using the global shutter applying the voltage domain method as illustrated in FIG. 7. On the other hand, unlike FIG. 7, where the first pixel signal output unit PO1 and the second pixel signal output unit PO2 are separately included, the first pixel signal output unit PO1 may be included in the second pixel signal output unit PO2.

For example, the first pixel signal output unit PO1 may convert an amount of the electric charges integrated to the first photo diode PD1 through the fourth photo diode PD4 into the first pixel signals XP1 in order through the storage region MEM, the second source-follower SF2, and the second selection transistor SX2, when the (1-1)-th mode signal MS11 through the (1-4)-th mode signal MS14 are activated. The first pixel signals XP1 may be output to the second column line CL2 in order.

Here, the storage region MEM may be electrically connected to the first photo diode PD1 through the fourth photo diode PD4 through the first mode transistor MX1. The operations of the (2-2)-th source-follower SF22 and the second selection transistor SX2 with respect to the electric charges of the first photo diode PD1 through the fourth photo diode PD4 stored in order in the storage region MEM may be the same as those of the first source-follower SF1 and the first selection transistor SX1 described above with reference to FIGS. 4 and 5.

The unit pixel 112 of FIGS. 9 and 10 may be miniaturized compared with that of FIGS. 4 and 7.

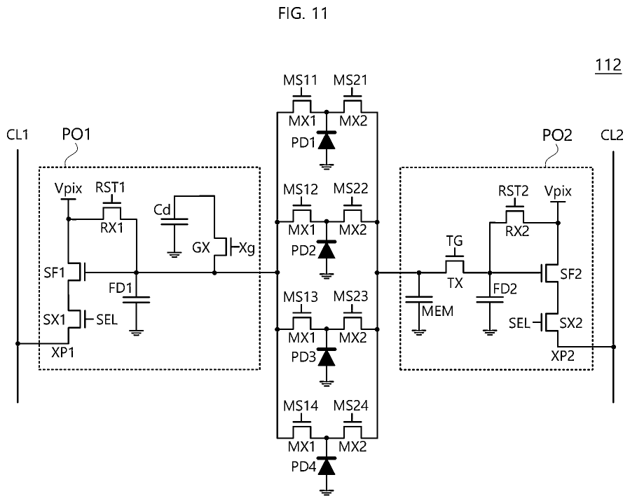

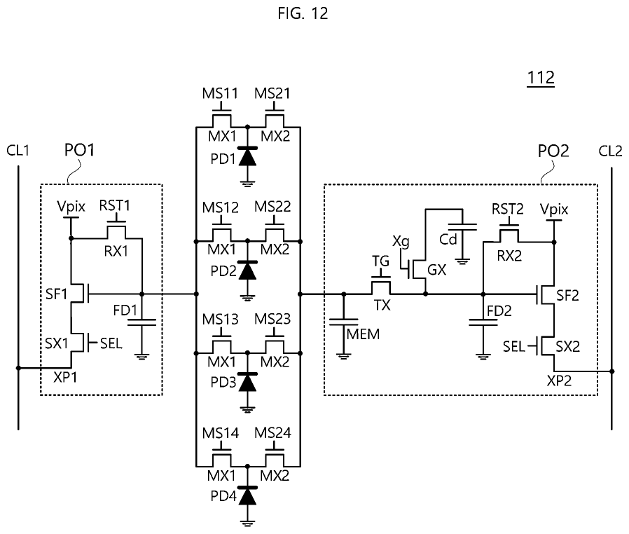

FIGS. 11 and 12 respectively illustrate the unit pixel 112 including a dual conversation gain function according to an embodiment of the present invention.

Referring to FIGS. 11 and 12, the unit pixel 112 according to an embodiment of the present invention may support a dual conversion gain mode that provides high conversion gain (HCG) and a low conversion gain (LCG). In this regard, at least one of the first pixel signal output unit PO1 and the second pixel signal output unit PO2 may further include a dynamic range capacitor Cd and a dual conversion gain transistor GX.

The dynamic range capacitor Cd may be used to expand capacity of a floating diffused region (for example, the first floating diffused region FD1 or the second floating diffused region FD2).

In a high illuminance mode, the dual conversion gain transistor GX connects the dynamic range capacitor Cd to the floating diffused region (FD1 or FD2) so that sampling may be performed with respect to a voltage level of the floating diffused region (FD1 or FD2) by LCG. On the other hand, in a low illuminance mode, the dual conversion gain transistor GX separates the dynamic range capacitor Cd and the floating diffused region (FD1 or FD2) so that sampling may be performed with respect to a voltage level of the floating diffused region (FD1 or FD2) by HCG. The high illuminance mode and the low illuminance mode may be set in response to a gain signal Xg. For example, the gain signal Xg may be applied to a gate of the dual conversion gain transistor GX.

FIG. 11 illustrates that the first pixel signal output unit PO1 includes the dynamic range capacitor Cd and the dual conversion gain transistor GX, whereas FIG. 12 illustrates that second pixel signal output unit PO2 includes the dynamic range capacitor Cd and the dual conversion gain transistor GX. In an embodiment, the first pixel signal output unit PO1 and the second pixel signal output unit PO2 both include the dynamic range capacitor Cd and the dual conversion gain transistor GX. For example, the first pixel signal output unit PO1 shown in FIG. 12 may be replaced with the first pixel signal output unit PO1 shown in FIG. 11.

Accordingly, the unit pixel 112 according to an embodiment of the present invention performs operations that are adaptive to illuminance and thus, may have increased performance in image sensing.

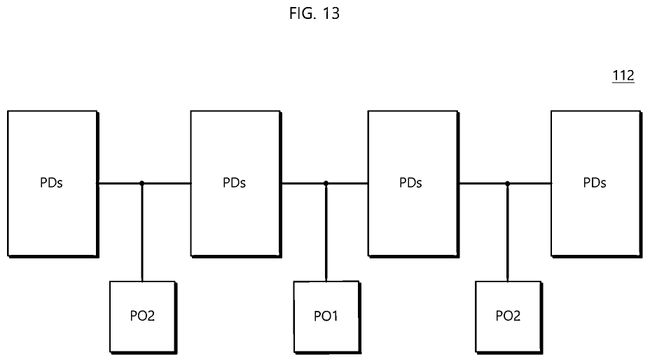

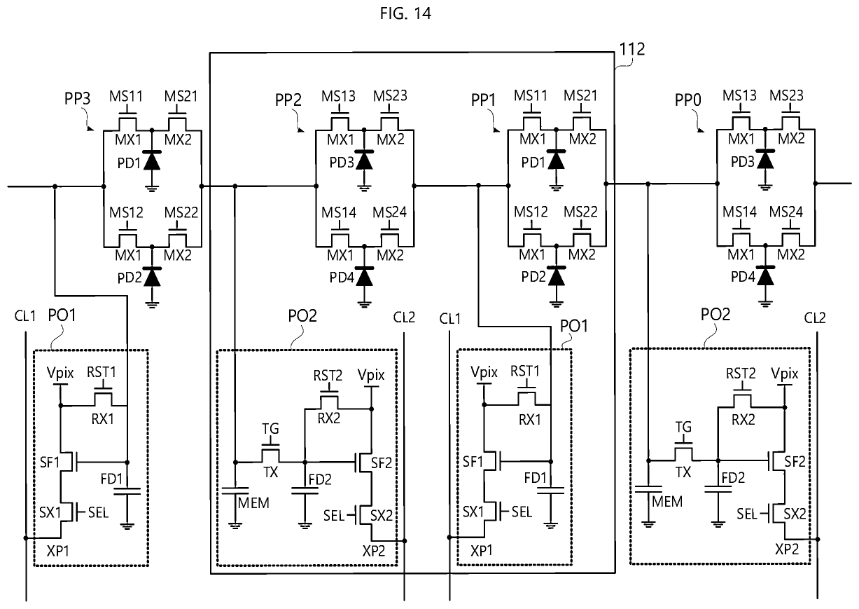

FIGS. 13 and 14 are respectively a block diagram and a circuit diagram illustrating the unit pixel 112 where the first and/or the second pixel signal output unit PO1 and/or PO2 is shared by the photo diodes PDs adjacent in a row direction according to an embodiment of the present invention.

Referring to FIGS. 13 and 14, the unit pixel 112 according to an embodiment of the present invention includes n photo diodes PDs, which are adjacent to each other in a column direction, and at least one of the first pixel signal output unit PO1 and the second pixel signal output unit PO2 may be shared by n photo diodes PDs and other n photo diodes PDs adjacent to n photo diodes PDs in a row direction.

For example, a pair of photo diodes PDs, which are adjacent to each other in a column direction, is disposed to be adjacent to another pair of photo diodes PDs in a row direction in FIG. 14. For example, a first pair PP1 of the first photo diode PD1 and the second photo diode PD2, which are adjacent to each other in a column direction, is adjacent to a second pair PP2 of the third photo diode PD3 and the fourth photo diode PD4, which are adjacent to each other in a column direction, in a row direction. FIG. 14 illustrates that each pair of photo diodes PDs includes two photo diodes PDs. However, the present invention is not limited thereto, and each pair of photo diodes PDs may include four photo diodes PDs as illustrated in FIG. 4.

Here, the first pair PP1 and the second pair PP2 may share the first pixel signal output unit PO1. Also, the first pair PP1 and the second pair PP2 may share the second pixel signal output unit PO2 with other adjacent pairs (for example, PP0 and PP3).

The operations of the first pixel signal output unit PO1 and the second pixel signal output unit PO2 may be the same as those described above. Accordingly, the unit pixel 112 according to an embodiment of the present invention may have increases in area efficiency. In addition, the unit pixel 112 according to an embodiment of the present invention may have the first pixel signal output unit PO1 or the second pixel signal output unit PO2 including n photo diodes PDs in various forms and thus, optimum miniaturization may be available as described in more detail below.

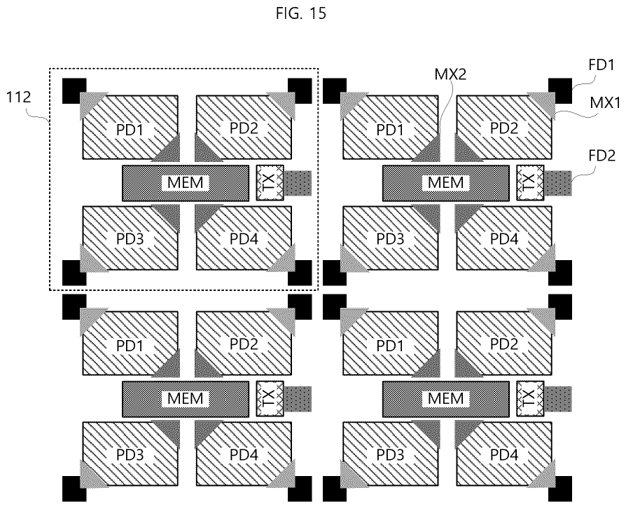

FIG. 15 illustrates a layout of the unit pixel 112 according to an embodiment of the present invention.

Referring to FIG. 15, the unit pixel 112 according to an embodiment of the present invention includes the plurality of photo diodes PDs, the storage region MEM, the first mode transistors MX1, and the second mode transistors MX2.

The plurality of photo diodes PDs each generate electric charges in response to incident light and are disposed to be adjacent to each other. FIG. 15 illustrates the unit pixel 112 including four photo diodes PDs in a 2×2 structure as in FIG. 14.

One storage region MEM is shared by the first photo diode PD1 through the fourth photo diode PD4. The photo diodes PDs and the storage region MEM may be formed on a substrate.

The storage region MEM may be formed on the position where the sum of the distances spaced apart from each photo diode PD is the smallest. When the first photo diode PD1 through the fourth photo diode PD4 are disposed in a 2×2 structure as in FIG. 15, the storage region MEM may be located at the center of the unit pixel 112. When the first photo diode PD1 through the fourth photo diode PD4 are disposed in a 1×4 structure as in FIG. 4, the storage region MEM may be located at the center of one of both sides of the first photo diode PD1 through the fourth photo diode PD4.

The number of the first mode transistors MX1 and the second mode transistors MX2 may each be the same as the number of photo diodes PDs.

In an embodiment, the first mode transistor MX1 overlaps a first region of the photo diode PD from among the first photo diode PD1 through the fourth photo diode PD4 by being spaced apart from a first direction. The first direction may be perpendicular to a layout plane of FIG. 15. That is, as the first mode transistor MX1 is stacked on a substrate, the first mode transistor MX1 may be spaced apart from the photo diode PD in a direction perpendicular to the substrate and may partially overlap the photo diode PD on a virtual plane projected on the substrate. In an embodiment, the second mode transistor MX2 overlaps a second region of the photo diode PD from among the first photo diode PD1 through the fourth photo diode PD4 by being spaced apart from the first direction.

Here, the second region may denote the region adjacent to the storage region MEM in the photo diode PD and the first region may denote the region spaced apart from the second region by a maximum distance in the photo diode PD. Accordingly, the unit pixel 112 according to an embodiment of the present invention may secure gate sizes of the transistors even in a demand for miniaturization so that malfunctions generated due to contact with the gates may be prevented. FIG. 15 illustrates that the first region corresponding to the first mode transistor MX1 and the second region corresponding to the second mode transistor MX2 are formed in the photo diode PD in a diagonal direction.

For reference, a source or drain region of each transistor may be formed on the substrate along with the photo diode PD or the storage region, and the gates may be formed on a wiring layer which is formed in the first direction (a vertical direction) of the substrate. An incident layer, on which light is incident and a micro-lens or a filter is formed, may face the wiring layer based on the substrate.

As illustrated in FIG. 4, the first mode transistor MX1 and the first floating diffused region FD1 may be electrically connected to each other. Also, the second mode transistor MX2 and the storage region MEM may be electrically connected to each other, and the storage region MEM and the second floating diffused region FD2 may be electrically connected to each other through the transmission transistor TX.

The plurality of first mode transistors MX1 may be turned on in order and the plurality of second mode transistors MX2 may be turned on at the same time.

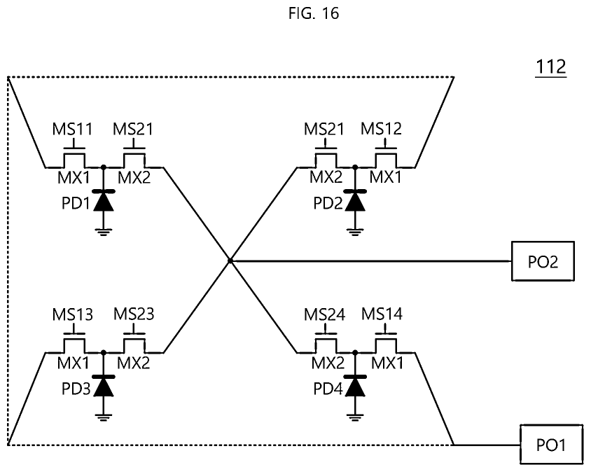

FIG. 16 is a circuit diagram that corresponds to the unit pixel 112 of FIG. 15 according an embodiment.

Referring to FIGS. 15 and 16, the first pixel signal output unit PO1 may be connected to four first mode transistors MX1 through a wiring extended along the outer edge of the unit pixel 112 and the second pixel signal output unit PO2 may be connected to four second mode transistors MX2 at a center region of the unit pixel 112. Due to this structure, the area of the unit pixel 112 may be reduced.

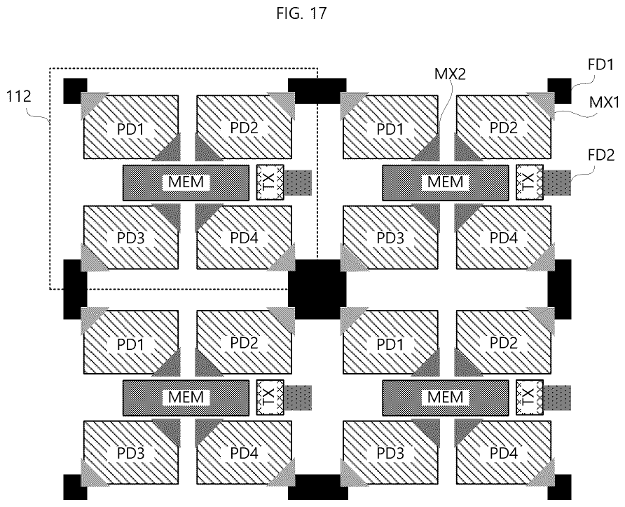

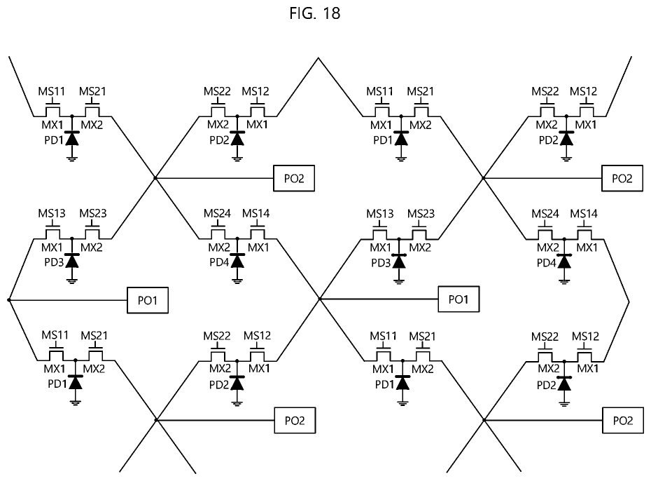

FIG. 17 illustrates a layout of the unit pixel 112 where the first floating diffused region FD1 is shared according to an embodiment of the present invention and FIG. 18 is a circuit diagram that corresponds to the unit pixel 112 of FIG. 17.

Referring to FIGS. 17 and 18, the unit pixel 112 of FIG. 17 may include the photo diodes PDs in a 2×2 structure, the storage region MEM may be formed on the center region where the average of the distances spaced apart from each photo diode PD is the smallest, and the first and second mode transistor MX1 and MX2 may be formed to have the maximum distance spaced apart from each other in the photo diode PD as in FIG. 15.

In addition, the first floating diffused region FD1 of FIG. 17 may be shared by the first mode transistors MX1 which are adjacent thereto. For example, the first floating diffused region FD1 may be shared by the first mode transistors MX1 of the fourth photo diode PD4 of the unit pixel 112, the third photo diode PD3 of the unit pixel adjacent to the fourth photo diode PD4 in a row direction, the second photo diode PD2 of the unit pixel adjacent to the fourth photo diode PD4 in a column direction, and a first photo diode PD1 of the unit pixel adjacent to the fourth photo diode PD4 in a diagonal direction.

Accordingly, as illustrated in FIG. 18, the first pixel signal output unit PO1 including the first floating diffused region FD1 may be disposed at the center region of four or two unit pixels 112 adjacent to each other. In this case, the average area of the unit pixel 112 may be reduced. Also, in the identical area condition, the unit pixel 112 may include the first floating diffused region FD1 having sufficient capacity and thus, image sensing operation may be performed with high-resolution.

FIGS. 15 through 18 illustrate the layout of the unit pixels and the corresponding circuits. However, the present invention is not limited thereto. For example, circuits having different forms may be realized to correspond to the layout of the unit pixels of FIG. 15.

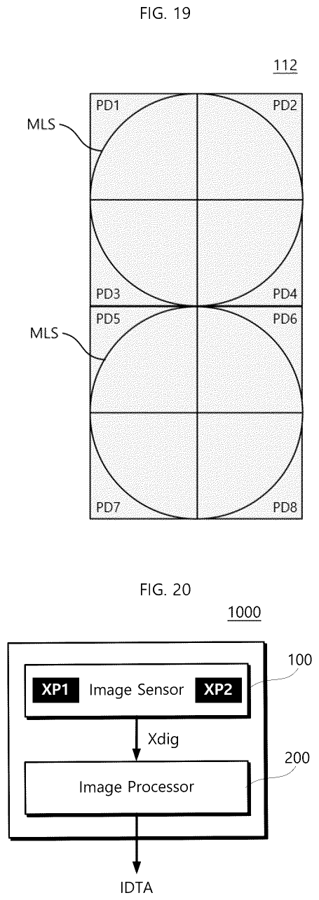

FIG. 19 illustrates the unit pixel 112 including an auto focusing function according to an embodiment of the present invention.

Referring to FIGS. 4 and 19, the unit pixel 112 according to an embodiment of the present invention includes one micro lens MLS and the first photo diode PD1 through the fourth photo diode PD4 sharing the micro lens MLS. Here, the operations of the first pixel signal output unit PO1 and the second pixel signal output unit PO2 are partially regulated to perform the auto focusing function by the unit pixel 112 according to an embodiment of the present invention.

For example, the first pixel signal output unit PO1 may convert amounts of the electric charges of some photo diodes PDs in order from among the plurality of photo diodes PD1 through PD4 and output the first pixel signal XP1, in response to the first mode signal MS1. Here, in response to the second mode signal MS2, the electric charges of the remaining photo diodes PDs from among the plurality of photo diodes PD1 through PD4 are stored together in the storage region MEM. Then, amounts of the electric charges stored together in the storage region MEM may be converted into one second pixel signal XP2 and the second pixel signal output unit PO2 may output the second pixel signal XP2.

In FIG. 19, the first pixel signal output unit PO1 shared by the first photo diode PD1 through the fourth photo diode PD4 may process the electric charges integrated to the first photo diode PD1 and the third photo diode PD3 in order at a first phase. At a next phase, the second pixel signal output unit PO2 may process the electric charges integrated to the remaining photo diodes PDs, that is, the second photo diode PD2 and the fourth photo diode PD4, at the same time.

In the same manner, the first pixel signal output unit PO1 shared by a fifth photo diode PD5 through an eighth photo diode PD8 may process the electric charges integrated to the fifth photo diode PD5 and a seventh photo diode PD7 in order at a first phase. At a next phase, the second pixel signal output unit PO2 may process the electric charges integrated to the remaining photo diodes PDs, that is, the sixth photo diode PD6 and the eighth photo diode PD8, at the same time.

In another example, the photo diodes PDs processed by the first pixel signal output unit PO1 may be the first photo diode PD1, the fourth photo diode PD4, the fifth photo diode PD5, and the eighth photo diode PD8 at the first phase. The remaining photo diodes PDs processed by the second pixel signal output unit PO2 may be the second photo diode PD2, the third photo diode PD3, the sixth photo diode PD6, and the seventh photo diode PD7 at the next phase. The first pixel signal XP1 and the second pixel signal XP2 processed at each phase are compared to each other to perform an auto focusing operation. In the unit pixel 112 according to an embodiment of the present invention, more accurate image sensing may be performed.

Instead of the first pixel signal XP1 and the second pixel signal XP2, a pair of first pixel signals XP1 or a pair of second pixel signals XP2 may be compared to each other to perform an auto focusing operation. The number of pairs of the pixel signals used in comparison is not limited.

Here, the first pixel signal output unit PO1 may convert amounts of the electric charges of some photo diodes PDs from among the plurality of shared photo diodes PDs into the first pixel signal XP1, output the first pixel signal XP1, and may not process other photo diodes PDs. For example, the first pixel signal output unit PO1 may process the electric charges integrated to the first photo diode PD1 and the third photo diode PD3 at the first phase and the second pixel signal output unit PO2 may process the electric charges integrated to the fifth photo diode PD5 and the seventh photo diode PD7 at the second phase. Accordingly, the remaining photo diodes PDs, that is, the second photo diode PD2, the fourth photo diode PD4, the sixth photo diode PD6, and the eighth photo diode PD8, may not be processed.

The second pixel signal output unit PO2 may function in the same manner. For example, the second pixel signal output unit PO2 may process the electric charges integrated to the first photo diode PD1 and the third photo diode PD3 at the first phase and the second pixel signal output unit PO2 may process the electric charges integrated to the fifth photo diode PD5 and the seventh photo diode PD7 at the second phase. Accordingly, the remaining photo diodes PDs, that is, the second photo diode PD2, the fourth photo diode PD4, the sixth photo diode PD6, and the eighth photo diode PD8, may not be processed.

When some of the photo diodes PDs are only processed as described above, high-speed operation may be available. Here, the pixel signal output unit for performing the operation may be selected based on a photographing condition. For example, when photographing environment is dark or an object does not move or moves only slightly, the first pixel signal output unit PO1 may be selected. When a moving picture is captured, the second pixel signal output unit PO2 may be selected.

As described above, in the unit pixel 112 according to an embodiment of the present invention, speed of processing the pixel signals may be increased and the photographing condition may be securely controlled.

According to the embodiments described above including the embodiment of FIG. 19, only the first pixel signal output unit PO1 processes each of the photo diodes PDs in order. However, the present invention is not limited thereto. For example, the first pixel signal output unit PO1 may process the first photo diode PD1 and the third photo diode PD3 at the first phase at the same time while performing an in auto focusing operation of FIG. 19. As such, since the photo diodes PDs corresponding to each phase are processed at the same time, performance in auto focusing may be increased.

According to the embodiments described above, except for the embodiment of FIG. 19, the second pixel signal output unit PO2 processes all shared photo diodes PDs. However, the present invention is not limited thereto and the second pixel signal output unit PO2 may process a part of the shared photo diodes PDs as needed, while in other operations except for auto focusing. For example, when the resolution required in capturing of moving objects is below a first standard, the second pixel signal output unit PO2 may process a part of the electric charges in the shared photo diodes PDs and reduce a load for signal processing.

FIG. 20 illustrates an image processing apparatus 1000 according to an embodiment of the present invention.

Referring to FIG. 20, the image processing apparatus 1000 according to an embodiment of the present invention includes the image sensor 100 and an image processor 200. The image sensor 100 may have a structure or may be operated using a method described with reference to FIGS. 1 through 19. The image processor 200 may receive a digital pixel signal Xdig that corresponds to the first pixel signal XP1 or the second pixel signal XP2 from the image sensor 100, may process the received digital pixel signal Xdig, and may output the processed signal as an image data IDATA. Accordingly, in the image processing apparatus 1000 according to an embodiment of the present invention, high-performance operations may be available and miniaturization or low-power consumption may be realized.

In the image sensor using a method of driving a hybrid shutter and the image processing apparatus including the same according to the present invention, a shutter driving method that is optimized in a required photographing mode may be used and miniaturization or low-power consumption may be realized.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An image sensor comprising:
n photo diodes which respectively generate electric charges in response to incident light and are adjacent to each other, where n is an integer equal to 2 or greater;
a first pixel signal output circuit shared by n photo diodes, wherein the first pixel signal output circuit converts an amount of the electric charges of each the n photo diodes in order into a first pixel signal in response to a first mode signal, and outputs the first pixel signal in order; and
a second pixel signal output circuit comprising a storage region shared by the n photo diodes, converts amounts of the electric charges of the n photo diodes stored together in the storage region or a voltage corresponding to the amounts of the electric charges of n photo diode into a second pixel signal in response to a second mode signal, and outputs the second pixel signal.

2. The image sensor of claim 1, further comprising n first mode transistors each of which comprises a first end connected to a corresponding photo diode from among the n photo diodes and a second other end connected to the first pixel signal output circuit and is gated in order by the first mode signal.

3. The image sensor of claim 2, wherein the first pixel signal output circuit comprises:
a first floating diffused region which stores the electric charges transmitted from a photo diode connected to an on-state first mode transistor from among the n first mode transistors;
a first source-follower which amplifies a voltage that corresponds to an amount of the electric charges stored in the first floating diffused region; and
a first selection transistor which outputs the first pixel signal that corresponds to the voltage output from the first source-follower, to a column line, in response to a column selection signal.

4. The image sensor of claim 2, wherein the first mode signal and the second mode signal are each activated at different times and the first pixel signal output circuit is located within the second pixel signal output circuit.

5. The image sensor of claim 1, further comprising n second mode transistors each of which comprises a first end connected to a corresponding photo diode from among the n photo diodes and a second other end connected to the second pixel signal output circuit and is gated at the same time by the second mode signal.

6. The image sensor of claim 1, wherein the second pixel signal output circuit comprises:
a transmission transistor which comprises a first end connected to the storage region and is gated by a transmission signal;
a second floating diffused region which comprises a first end connected to a second other end of the transmission transistor and stores the electric charges transmitted from the storage region;
a second source-follower which amplifies a voltage that corresponds to amounts of the electric charges stored in the second floating diffused region; and
a second selection transistor which outputs the second pixel signal, that corresponds to the voltage output from the second source-follower, to the column line, in response to the column selection signal.

7. The image sensor of claim 6, further comprising n first mode transistors each of which comprises a first end connected to a corresponding photo diode from among the n photo diodes and a second other end connected to the second floating diffused region and is gated in order by the first mode signal, wherein when n first mode transistors are turned on in order, the second floating diffused region, the second source-follower, and the second selection transistor are operated as the first pixel signal output circuit, the second floating diffused region stores in order the electric charges transmitted from a photo diode connected to a on-state first mode transistor from among the n first mode transistors, and the second selection transistor outputs the first pixel signal, that corresponds to the voltage output from the second source-follower, to the column line in order, in response to the column selection signal.

8. The image sensor of claim 1, wherein the second pixel signal output circuit comprises:
a second floating diffused region which stores the electric charges transmitted from the n photo diodes;
a (2-1)-th source-follower which transmits a voltage, that corresponds to amounts of the electric charges stored in the second floating diffused region, to a first node;
a precharge transistor which comprises a first end connected to the (2-1)-th source-follower at the first node and precharges the first node, in response to a precharge signal;
a sampling transistor which comprises a first end connected to the first node and a second other end connected to the storage region at a second node and is gated by a sampling signal;
a (2-2)-th source-follower which comprises a gate connected to the second node and amplifies a voltage that corresponds to the storage region; and
a second selection transistor which outputs the second pixel signal, that corresponds to the voltage output from the (2-2)-th source-follower, to the column line, in response to the column selection signal.

9. The image sensor of claim 1, wherein at least one of the first pixel signal output circuit and the second pixel signal output circuit comprises:
a floating diffused region;
a dynamic range capacitor which is used to expand capacity of the floating diffused region; and
a dual conversion gain transistor which connects the dynamic range capacitor to the floating diffused region in a high illuminance mode and separates the dynamic range capacitor and the floating diffused region in a low illuminance mode.

10. The image sensor of claim 1, wherein the n photo diodes are adjacent to each other in a column direction and at least one of the first pixel signal output circuit and the second pixel signal output circuit is shared by the n photo diodes and other n photo diodes adjacent to the corresponding photo diodes from among n photo diodes in a row direction.

11. The image sensor of claim 1, wherein the first pixel signal output circuit converts amounts of the electric charges of some photo diodes from among the n photo diodes into the first pixel signal and outputs the first pixel signal in order or at the same time, in response to the first mode signal, and the second pixel signal output circuit outputs the second pixel signal that corresponds to amounts of the electric charges of the remaining photo diodes from among n photo diodes, in response to the second mode signal.

12. The image sensor of claim 1, wherein the first pixel signal output circuit converts amounts of the electric charges of some photo diodes from among the n photo diodes into the first pixel signal and outputs the first pixel signal in order or at the same time, in response to the first mode signal.

13. The image sensor of claim 1, wherein the second pixel signal output circuit outputs the second pixel signal that corresponds to amounts of the electric charges of some photo diodes from among the n photo diodes, in response to the second mode signal.

14. The image sensor of claim 1, wherein the first pixel signal output circuit is operated by using a rolling shutter driving method, in response to the first mode signal, and the second pixel signal output circuit is operated by using a global shutter driving method, in response to the second mode signal.

15. An image sensor comprising:
n photo diodes which respectively generate electric charges in response to incident light and are adjacent to each other, where n is an integer equal to 2 or greater;
n first mode transistors which overlap a first region of a corresponding photo diode from among the n photo diodes while being spaced apart from one another in a first direction;
a storage region shared by the n photo diodes; and
n second mode transistors which overlap a second region adjacent to the storage region of a corresponding photo diode from among the n photo diodes while being spaced apart from one another in the first direction.

16. The image sensor of claim 15, wherein the storage region is formed on a position where a sum of distances spaced apart from each of the n photo diodes is the smallest.

17. The image sensor of claim 15, wherein the first region and the second region are spaced apart from each other by a maximum distance in a corresponding photo diode.

18. The image sensor of claim 15, further comprising first floating diffused regions each shared by an adjacent first mode transistor from among the n first mode transistors.

19. The image sensor of claim 15, wherein the n first mode transistors are turned on in order and the n second mode transistors are turned on at the same time.

20. An image processing apparatus comprising:
the image sensor of claim 1; and
an image processor which receives a digital pixel signal corresponding to the first pixel signal or the second pixel signal from the image sensor to generate image data.
